(19) United States
(12) Patent Application Publication
(10) Pub. No.: US 2024/0153863 A1
(43) Pub. Date: May 9, 2024

(54) SEMICONDUCTOR PACKAGE AND MANUFACTURING METHOD THEREOF

(71) Applicant: SAMSUNG ELECTRONICS CO., LTD., Suwon-si (KR)

(72) Inventors: Kyoungok JUNG, Suwon-si (KR); Jakyoung GU, Suwon-si (KR)

(21) Appl. No.: 18/219,211

(22) Filed: Jul. 7, 2023

(30) Foreign Application Priority Data
Nov. 4, 2022 (KR) 10-2022-0146384

(51) Int. Cl. H01L 23/498; H01L 23/31; H01L 23/538; H01L 25/065; H01L 25/10; H10B 80/00

(52) U.S. Cl. CPC H01L 23/49866; H01L 23/3128; H01L 23/49811; H01L 23/49822; H01L 23/5383; H01L 25/0652; H01L 25/105; H10B 80/00; H01L 24/16; H01L 2224/16225

(57) ABSTRACT

A semiconductor package including, a first redistribution substrate including a first body layer and a first wiring layer in the first body layer, a semiconductor chip on the first redistribution substrate, a through post around the semiconductor chip and on the first redistribution substrate, and a second redistribution substrate on the semiconductor chip and the through post, wherein, the first wiring layer includes a first titanium seed layer, and the first titanium seed layer has a vertical cross-section of a trapezoid structure in which a top surface is narrow and a bottom surface is wide.

### CROSS-REFERENCE TO RELATED APPLICATION

Korean Patent Application No. 10-2022-0146384, filed on Nov. 4, 2022, in the Korean Intellectual Property Office, is incorporated by reference herein in its entirety.

### BACKGROUND

### 1. Field

A semiconductor package and manufacturing method thereof is disclosed.

### 2. Description of the Related Art

A semiconductor package and a method of manufacturing a semiconductor package including a redistribution substrate and a method of manufacturing the semiconductor package is disclosed.

### SUMMARY

Embodiments are directed to a semiconductor package including a first redistribution substrate including a first body layer and a first wiring layer in the first body layer, a semiconductor chip on the first redistribution substrate, a through post around the semiconductor chip and on the first redistribution substrate, and a second redistribution substrate on the semiconductor chip and the through post, wherein the first wiring layer includes a first titanium seed layer, and the first titanium seed layer has a vertical cross-section of a trapezoid structure in which a top surface is narrow and a bottom surface is wide.

Embodiments are directed to a semiconductor package including a first redistribution substrate, semiconductor chips on the first redistribution substrate, a through post around the semiconductor chips and on the first redistribution substrate, a sealing material surrounding a side surface of the through post, and covering and sealing the semiconductor chips, a second redistribution substrate on the sealing material and the through post, and an external contact terminal in a fan-out structure on a bottom surface of the first redistribution substrate, wherein, the first redistribution substrate and the second redistribution substrate each include a body layer and a wiring layer in the body layer, the wiring layer includes a first titanium seed layer having a vertical cross-section of a trapezoid structure in which a top surface is narrow and a bottom surface is wide, a copper layer on the first titanium seed layer, and a copper wiring on the copper seed layer, and a side slope of the trapezoid structure is from about 65° to about 90°.

Embodiments are directed to a method of manufacturing a semiconductor package including forming a first redistribution substrate on a carrier substrate, forming a through post on a peripheral portion of the first redistribution substrate, stacking semiconductor chip on a center portion of the first redistribution substrate, forming a sealing material covering the through post and the semiconductor chips, grinding an upper portion of the sealing material to expose a top surface of the through post, and forming a second redistribution substrate on the through post and the sealing material, wherein, the first redistribution substrate and the second redistribution substrate each include a body layer and a wiring layer in the body layer, the wiring layer includes a first titanium seed layer having a cross-section of a trapezoid structure in which a top surface is narrow and a bottom surface is wide, and the first titanium seed layer includes a fluoride etchant.

### BRIEF DESCRIPTION OF THE DRAWINGS

Features will become apparent to those of skill in the art by describing in detail exemplary embodiments with reference to the attached drawings in which:

FIG. 1 is a cross-sectional view of a structure of a semiconductor package according to an example embodiment.

FIGS. 2A and 2B are respectively a cross-sectional view and an enlarged cross-sectional view of a portion of a first wiring layer of a first redistribution substrate in the semiconductor package shown in FIG. 1.

FIG. 3 is a graph of sizes of undercuts of a wiring layer according to etching time lengths on a Ti seed layer.

FIGS. 4A and 4B are cross-sectional views of various wiring layer structures of the first redistribution substrate of the semiconductor package shown in FIG. 1.

FIGS. 5A to 5F are cross-sectional views of a process of manufacturing the first redistribution substrate shown in FIG. 2A.

FIGS. 6A to 6C are enlarged cross-sectional views of a portion A of the semiconductor package shown in FIG. 1.

FIGS. 7 to 10 are cross-sectional views of a structure of a semiconductor package according to example embodiments.

FIGS. 11A to 11L are cross-sectional views of a process of manufacturing the semiconductor package shown in FIG. 1.

### DETAILED DESCRIPTION

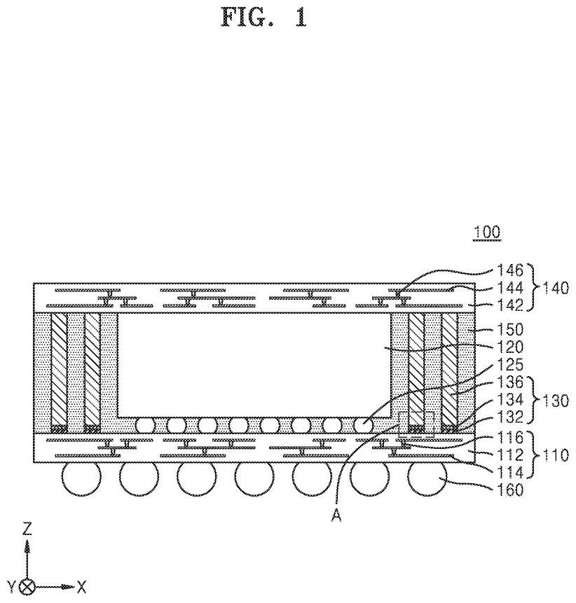

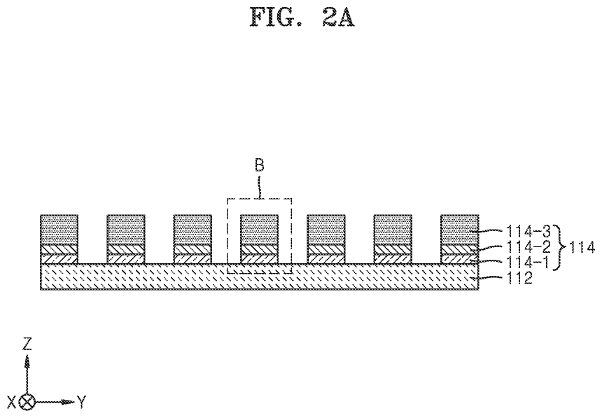

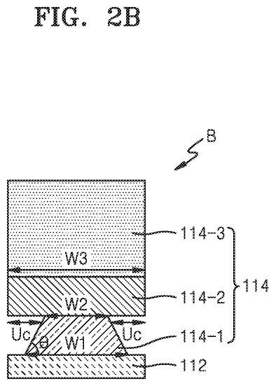

FIG. 1 is a cross-sectional view of a structure of a semiconductor package 100 according to an example embodiment, FIGS. 2A and 2B are respectively a cross-sectional view and an enlarged cross-sectional view of a first wiring layer of a first redistribution substrate 110 in the semiconductor package 100 shown in FIG. 1. For reference, FIG. 2B is an enlarged cross-sectional view of portion B shown in FIG. 2A, and in FIG. 2A, a first body layer between the first wiring layers and above the first wiring layers is omitted.

Referring to FIGS. 1 to 2B, a semiconductor package 100 of the present embodiment may include the first redistribution substrate 110, a semiconductor chip 120, a through post 130, a second redistribution substrate 140, a sealing material 150, and an external contact terminal 160.

The first redistribution substrate 110 may be under the semiconductor chip 120 and may redistribute a chip pad of the semiconductor chip 120 to a periphery of the semiconductor chip 120. The first redistribution substrate 110 may include a first body layer 112, a first wiring layer 114, and a first via contact 116.

The first body layer 112 may include a polymer layer. In an implementation, the first body layer 112 may be a photo imageable dielectric (PID) resin, and may further include an inorganic filler. The first body layer 112 may have a multiple-layer structure according to a multiple-layer structure of the first wiring layer 114. However, for convenience, the first body layer 112 in FIG. 1 is shown as a single layer structure. When the first body layer 112 has the multiple-layer structure, the first body layer 112 may include a same material or a plurality of different materials.

Pads may be on top and bottom surfaces of the first body layer 112. In an implementation, the external contact terminal 160 may be in a bottom pad on the bottom surface of the first body layer 112, and bumps 125 of the semiconductor chip 120 may be in a top pad on the top surface of the first body layer 112. The top pad and bottom pad may be connected to each other through the first wiring layer 114 and the first via contact 116.

The external contact terminal 160 may be on a bottom center portion of the first redistribution substrate 110 corresponding to a bottom surface of the semiconductor chip 120 and on a bottom outer portion of the first redistribution substrate 110 extending outwards from the bottom center portion of the first redistribution substrate 110. To conclude, the first redistribution substrate 110 may redistribute the bumps 125 of the semiconductor chip 120 to a region wider than the bottom surface of the semiconductor chip 120 through the first wiring layer 114 and the external contact terminal 160. For reference, a package structure like this, in which the external contact terminals are widely arranged on the bottom surface of a package substrate out of the bottom surface of the semiconductor chip, is referred to as a fan-out (FO) package structure. On the other hand, a package structure in which the external contact terminals are only in the bottom portion of a package substrate corresponding to the bottom surface of the semiconductor chip is referred to as a fan-in (FI) package structure.

As shown in FIG. 1, the first wiring layer 114 may be arranged in a multiple-layer structure within the first body layer 112. The first wiring layers 114 adjacent to one another in a third direction (the Z direction) may be connected to one another through the first via contact 116. In a certain layer, the first wiring layers 114 may extend in a first direction (the X direction) and may be apart from one another in a second direction (the Y direction). The X direction may be perpendicular to the Y direction. In other words, in a certain layer, the first wiring layers 114 may be in a line & space (L&S) structure in the second direction (the Y direction). In an implementation, in a certain layer, only one first wiring layer 114 may be arranged, or alternatively, a plurality of the first wiring layers 114 may have different widths and/or at different intervals. In a certain layer, the plurality of first wiring layers 114 may be arranged in different directions. The first wiring layer 114 may include a first Ti seed layer 114-1, a first Cu seed layer 114-2, and a Cu wiring 114-3. More details of a structure of the first wiring layer 114 will be described later with reference to FIGS. 2A and 2B.

The semiconductor chip 120 may be mounted in a flip-chip structure on the first redistribution substrate 110 through the bump 125. As shown in FIG. 1, the semiconductor chip 120 may be in a center of the first redistribution substrate 110. In addition, the semiconductor chip 120 may be in the center of the first redistribution substrate 110 in the second direction (the Y direction).

The semiconductor chip 120 may include a logic semiconductor chip. In an implementation, the logic semiconductor chip may include an application processor (AP), a micro-processor, a central processing unit (CPU), a controller, or an application specific integrated circuit (ASIC). In addition, the semiconductor chip 120 may construct a GPU/CPU/SOC chip, and according to types of the semiconductor chip 120, the semiconductor package 100 may be distinguished to be a server-oriented semiconductor device or a mobile-oriented semiconductor device. In an implementation, in some embodiments, the semiconductor chip 120 may also include a memory semiconductor chip. As used herein, the term “or” is not an exclusive term, e.g., “A or B” would include A, B, or A and B.

As the semiconductor chip 120 may be mounted above the first redistribution substrate 110 in the flip-chip structure, the bottom surface of the semiconductor chip 120 may include an active surface, and a top surface of the semiconductor chip 120, which may be opposite to the bottom surface of the semiconductor chip 120, and may include an inactive surface. In addition, chip pads may be on the bottom surface of the semiconductor chip 120, and the bumps 125 may be on the chip pads. The chip pads may be electrically connected to other components in the semiconductor chip 120, e.g., an integrated circuit. In an implementation, multiple wiring layers may be on the bottom surface of the semiconductor chip 120, and the chip pads may be electrically connected to the integrated circuit in the semiconductor chip 120 through the multiple wiring layers.

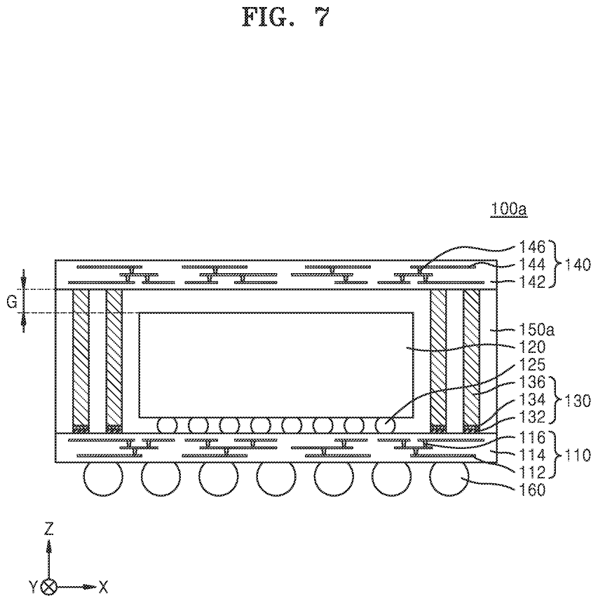

As shown in FIG. 1, the top surface of the semiconductor chip 120 may directly contact a bottom surface of a second redistribution substrate 140. In other words, the sealing material 150 may be not between the semiconductor chip 120 and the second redistribution substrate 140. However, according to embodiments, the sealing material 150 may be between the semiconductor chip 120 and the second redistribution substrate 140. Embodiments thereof will be described in further detail in descriptions with reference to FIG. 7.

The through post 130 may be between the first redistribution substrate 110 and the second redistribution substrate 140. As the sealing material 150 may be between the first redistribution substrate 110 and the second redistribution substrate 140, the through post 130 may extend through the sealing material 150. The through post 130 may electrically connect the first redistribution substrate 110 and the second redistribution substrate 140. In an implementation, a bottom surface of the through post 130 may be connected to a top pad of the first redistribution substrate 110, and a top surface of the through post 130 may be connected to a second via contact 146 of the second redistribution substrate 140.

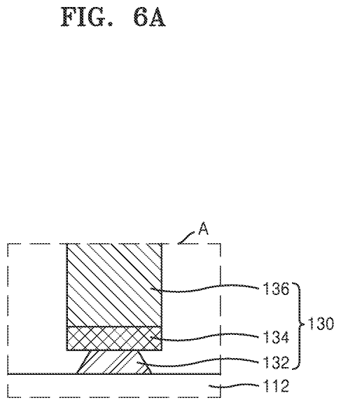

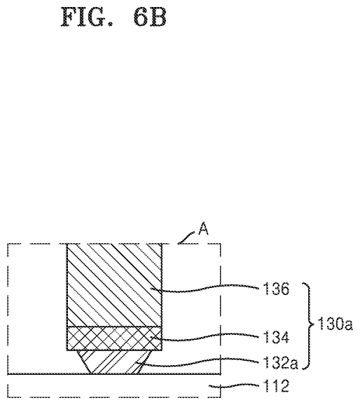

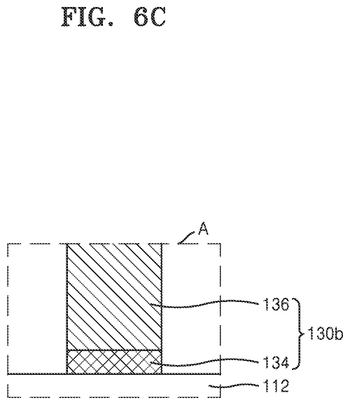

The through post 130 may include seed metal layers (e.g., a third Ti seed layer 132 and a second Cu seed layer 134) and a Cu post 136. The seed metal layers (e.g., the third Ti seed layer 132 and the second Cu seed layer 134) may be on the first redistribution substrate 110, and the Cu post 136 may be on the seed metal layers (e.g., the third Ti seed layer 132 and the second Cu seed layer 134). More details of a structure of the through post 130 will be further described in descriptions with reference to FIGS. 6A to 6C.

The second redistribution substrate 140 may be on the semiconductor chip 120, the through post 130, and the sealing material 150. The second redistribution substrate 140 may have a structure similar to a structure of the first redistribution substrate 110. In an implementation, the second redistribution substrate 140 may include a second body layer 142, a second wiring layer 144, and the second via contact 146. Descriptions of the second body layer 142, the second wiring layer 144, and the second via contact 146 may be the same as descriptions of the first body layer 112, the first wiring layer 114, and the first via contact 116 of the first redistribution substrate 110.

In the second redistribution substrate 140, the second via contact 146 may connect the second wiring layers 144 adjacent to one another in the third direction (the Z direction), and may connect the second wiring layer 144 and the through post 130. In addition, the second wiring layer 144 of the second redistribution substrate 140 may be electrically connected to the semiconductor chip 120 and the external contact terminal 160 through the through post 130 and the first wiring layer 114 of the first redistribution substrate 110.

A first passivation layer may be on a bottom surface of the first redistribution substrate 110, and a second passivation layer may be on a top surface of the second redistribution substrate 140. The first passivation layer may cover and protect the bottom surface of the first redistribution substrate 110, and the second passivation layer may cover and protect the top surface of the second redistribution substrate 140. The first passivation layer and the second passivation layer may include an insulating material, an oxide film, a nitride film, or an oxynitride film. In an implementation, the first passivation layer and the second passivation layer may also include a solder resist (SR) or a resin.

The sealing material 150 may be between the first redistribution substrate 110 and the second redistribution substrate 140. The sealing material 150 may cover and seal a side surface of the semiconductor chip 120. In some embodiments, the sealing material 150 may cover the top surface of the semiconductor chip 120. In addition, the sealing material 150 may surround a side surface of the through post 130. As shown in FIG. 1, the sealing material 150 may surround the side surface of the semiconductor chip 120 and fill a gap between the bumps 125 on the bottom surface of the semiconductor chip 120. However, in some embodiments, a underfill may fill the gap between the bumps 125 on the bottom surface of the semiconductor chip 120, and the sealing material 150 may only surround side surfaces of the semiconductor chip 120 and the underfill.

The sealing material 150 may include an insulating material, e.g., a thermoset resin such as epoxy resin, a thermoplastic resin such as polyimide, or a resin including an reinforcing material such as an inorganic filler in addition to the thermoset resin or thermoplastic resin, more particularly, ABF, FR-4, BT resins. In addition, a molding material such as EMC or a photosensitive material such as photo imageable encapsulant (PIE) may be used for the sealing material 150.

As described above, the external contact terminal 160 may be a bottom pad on the bottom surface of the first redistribution substrate 110 and may be electrically connected to the first wiring layer 114 through the bottom pad. The external contact terminal 160 may connect the semiconductor package 100 to a package substrate, or a main board of an electronic device. The external contact terminal 160 may include a conductive material, e.g., solder, tin (Sn), silver (Ag), copper (Cu), or aluminum (Al).

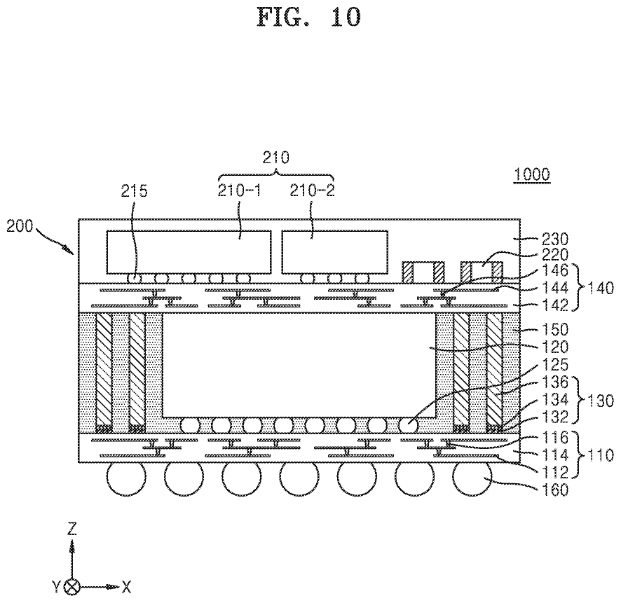

At least one semiconductor chip and/or at least one passive element may be stacked on the top surface of the second redistribution substrate 140. In addition, the at least one semiconductor chip and/or at least one passive element having an upper package structure may be stacked on the second redistribution substrate 140. A structure of the semiconductor package in which the upper package is stacked on the second redistribution substrate 140 may correspond to a package on package (POP) structure. A semiconductor package having the POP structure will be described in further detail with reference to FIG. 10.

As shown in FIG. 2A, in the semiconductor package 100 according to the present embodiment, the first wiring layers 114 may extend in a first direction (the X direction) and may be apart from one another in the second direction (the Y direction). In other words, the first wiring layers 114 may be arranged in an L/S structure in the second direction (the Y direction). In the semiconductor package 100 of the present embodiment, the first wiring layers 114 may have a width and an interval less than or equal to 5 μm in the second direction (the Y direction). In other words, the width of the first wiring layer 114 in the second direction (the Y direction) may be less than or equal to 5 μm, and the interval between the first wiring layers 114 adjacent to one another may be less than or equal to 5 μm. The first wiring layer 114 may be connected to another first wiring layer 114 in an upper layer or a lower layer through the first via contact 116. Furthermore, according to embodiments, the first wiring layer 114 may also be connected to the bottom pad on the bottom surface of the first body layer 112 or the top pad on the top surface of the first body layer 112.

The first wiring layer 114 may include the first Ti seed layer 114-1, the first Cu seed layer 114-2, and the Cu wiring 114-3. As shown in FIG. 2B, the first Ti seed layer 114-1 may have a trapezoid structure in which an upper portion is narrow and a bottom portion is wide, in the second direction (the Y direction). On the other hand, the first Cu seed layer 114-2 and the Cu wiring 114-3 may have a shape in which a width in the second direction (the Y direction) may be approximately uniform in the third direction (the Z direction).

To further describe a structure of the first Ti seed layer 114-1, when widths of a bottom surface and a top surface of the first Ti seed layer 114-1 in the second direction (Y direction) are respectively a first width W1 and a second width W2 and a width of a bottom of the first Cu seed layer 114-2 is a third width W3, sizes of the widths may decrease in orders of the third width W3, the first width W1, and the second width W2.

Here, the first width W1 may be smaller than the third width W3, and may be equal to or greater than the second width W2. In addition, a ratio of the first width W1 to the third width W3 may be 90% or higher. In terms of an area, an area of the bottom surface of the first Ti seed layer 114-1 may be equal to or greater than 80% of an area of the bottom surface of the first Cu seed layer 114-2. In terms of the trapezoid structure of the first Ti seed layer 114-1, an angle θ of a side surface of the trapezoid may be from about 65° to about 90°. When the angle θ of the side surface of the trapezoid is 90°, the first width W1 may be substantially identical to the second width W2.

The second width W2 may be smaller than the third width W3 and may have a ratio of at least 80% to the third width W3. In terms of areas, an area of a top surface of the first Ti seed layer 114-1 may be equal to or greater than 65% of the area of bottom surface of the first Cu seed layer 114-2. In the semiconductor package 100 according to the present embodiment, e.g., the second width W2 may be equal to or greater than 90% of the third width W3. Again, in terms of areas, the area of the top surface of the first Ti seed layer 114-1 may be equal to or greater than 80% of the area of the bottom surface of the first Cu seed layer 114-2.

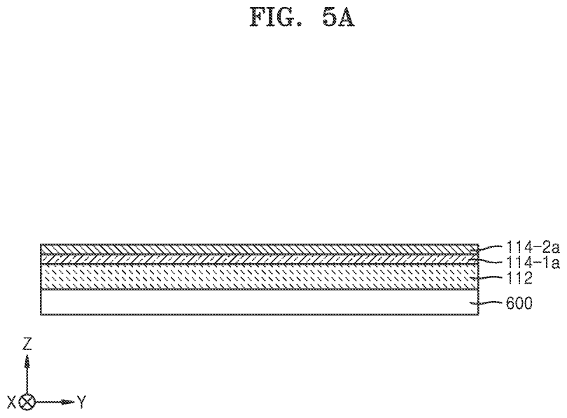

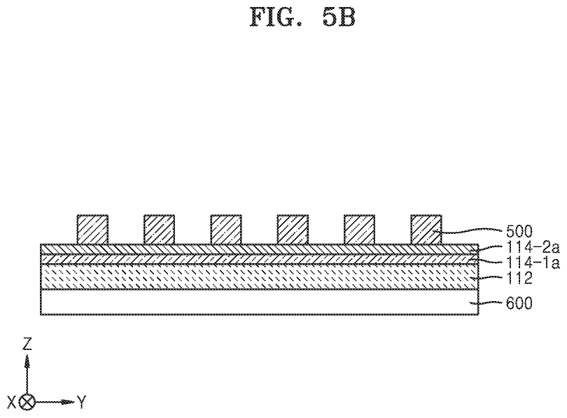

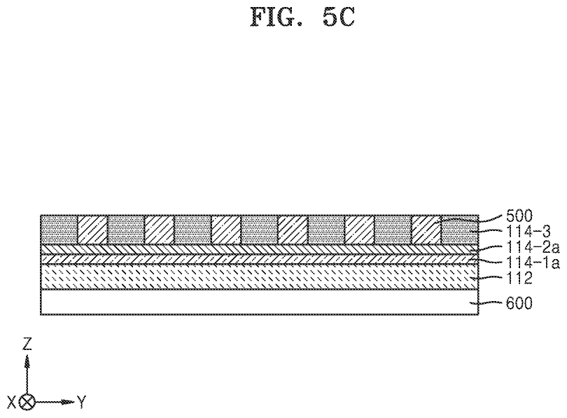

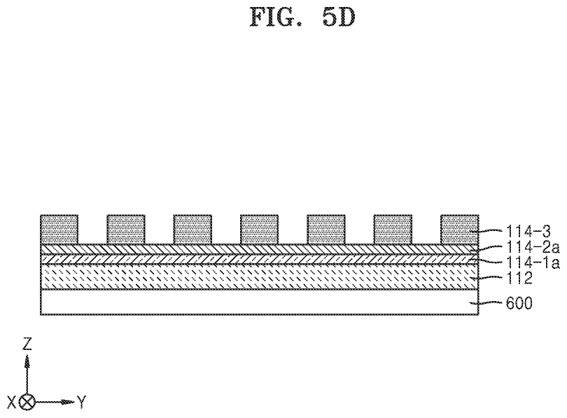

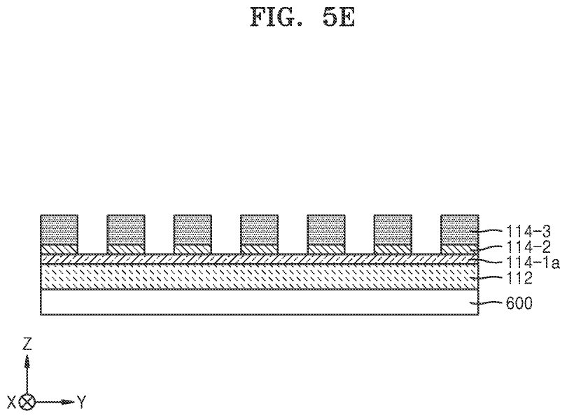

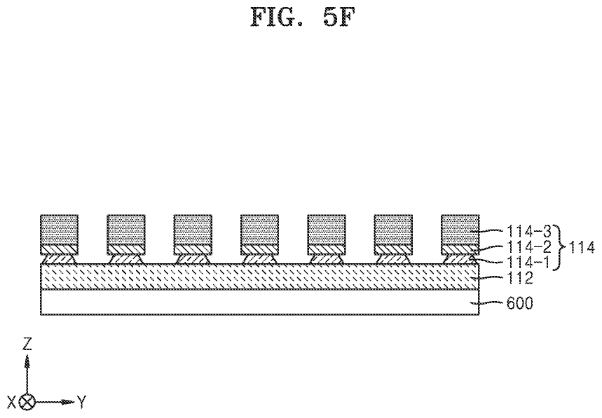

The trapezoid structure of the first Ti seed layer 114-1 may be caused due to use of a fluoride etchant in an etching process of forming the first Ti seed layer 114-1. The process of forming the first Ti seed layer 114-1 using a fluoride etchant will be further described with reference to FIGS. 5A to 5F.

In the semiconductor package 100, the first redistribution substrate 110 may have at least one first wiring layer 114 in the first body layer 112, and the first wiring layer 114 may have, e.g., an L/S structure. In addition, the first wiring layer 114 may include the first Ti seed layer 114-1, the first Cu seed layer 114-2, and the Cu wiring 114-3, and the first Ti seed layer 114-1 may have the trapezoid structure in which an upper portion is narrow and a bottom portion is wide. As the first Ti seed layer 114-1 has the trapezoid structure, an adhesion between the first Ti seed layer 114-1 and a lower layer to which a bottom surface of the first Ti seed layer 114-1 contacts, e.g., a polymer layer, increases, and accordingly, delamination defects may be effectively prevented. As a result, signal transmission defects of the first redistribution substrate 110 may be improved, and the reliability of the entire semiconductor package 100 may be improved.

For reference, in a semiconductor package according to Comparative Examples, a Ti seed layer in a wiring layer of a redistribution layer may be formed using an H₂O₂/KOH etchant (hereinafter, referred to as ‘H₂O₂ etchant’). In detailed examples, when a Ti seed layer is formed using H₂O₂ etchant for a wiring layer having a L/S structure of 7 μm/8 μm, due to a high etch rate and over etching, undercuts occur less than 10%, and the Ti seed layer may be in a reverse-trapezoid structure in which a lower portion is narrow, and an upper portion is wide. However, as the wiring layer has a sufficiently great width, an adhesion with a lower layer may be well secured. However, when the L/S structure of the wiring layer is 5 μm/5 μm or smaller, e.g., 2 μm/2 μm, 20% or more undercuts may occur in over etching using H₂O₂ etchant, and as the adhesion with the lower layer is weakened, detachment defects and/or signal transmission defects may occur. More particularly, in the case of the reverse-trapezoid structure of the Ti seed layer, a bottom surface of the Ti seed layer forming a heterointerface may have a contact area smaller than that of a top surface of the Ti seed layer forming a homointerface, and therefore, danger of signal transmission defects may further increase. Here, the heterointerface may indicate an interface between the bottom surface of the Ti seed layer and a top surface of the polymer layer, and the homointerface may indicate an interface between the top surface of the Ti seed layer and a bottom surface of the Cu seed layer.

When forming the Ti seed layer, generally over etching (e.g., 200% over etching) may be performed, and this may be to completely remove a portion of an initial Ti seed layer 114-1a (see FIG. 5A) exposed between the Cu wirings 114-3. Over etching may be defined according to an etching time length. In an implementation, when an appropriate etching time length is TO, an etching time length that is twice TO may correspond to 200% over etching. In addition, an undercut, which indicates an inward depth with reference to a side surface of an upper layer, may be simply indicated as a length, or may be indicated as a ratio to a total width. In an implementation, when a width of a wiring layer is 7 μm and a undercut about 0.4 μm occurs due to 200% over etching, it may be considered that a undercut having a ratio of 0.4/7*100, i.e., 5.7%, has occurred. When the width of the wiring layer is 2 μm and a undercut about 0.4 μm occurs due to 200% over etching, it may be considered that a undercut having a ratio of 0.4/2*100, i.e., 20%, has occurred.

On the other hand, in the semiconductor package 100 according to the present embodiment, the first Ti seed layer 114-1 in the first wiring layer 114 of the first redistribution substrate 110 may be formed using a fluoride etchant. Accordingly, the first Ti seed layer 114-1, which has a great undercut Uc on the top surface, may have a trapezoid structure having a smaller upper portion and greater lower portion. Accordingly, the bottom surface of the first Ti seed layer 114-1 forming the heterointerface has a contact area greater than that of the top surface of the first Ti seed layer 114-1 forming the homointerface, and as a result, detachment defects and/or signal transmission defects may be improved.

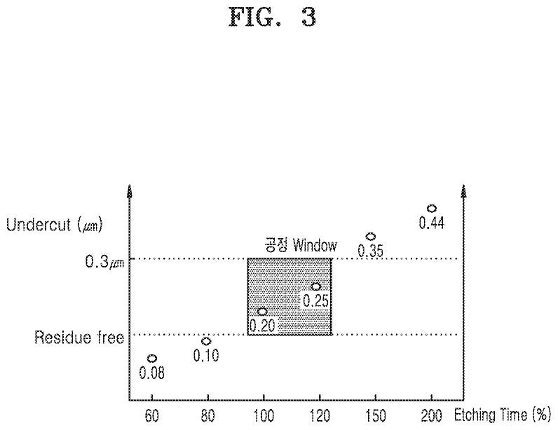

FIG. 3 is a graph of sizes of undercuts of a wiring layer according to etching time lengths on a Ti seed layer. X axis indicates an etching time length in % unit, and Y axis sizes of undercuts in units of micrometers (μm).

Referring to FIG. 3, a process window indicates an undercut in a bottom surface of the Ti seed layer in which the Ti seed layer may maintain a stable adhesion with the lower layer. More particularly, to be included in the process window, portions of the initial seed layer 114-1a (see FIG. 5A) may be exposed between the Cu wirings 114-3, completely removed and the undercut in the bottom surface of the Ti seed layer may be less than or equal to 0.3 Here, ‘Residue free’ may indicate a state in which the exposed portions of the initial Ti seed layer are completely removed.

As described above, to completely remove the exposed portions of the initial Ti seed layer, generally 200% over etching may be performed, and accordingly, as shown in the graph, the semiconductor package according to the Comparative Example may not be included in the process window. However, in the case of the semiconductor package 100 according to the present embodiment, due to the trapezoid structure of the first Ti seed layer 114-1, even when a undercut on the top surface of the first Ti seed layer 114-1 after 200% over etching is greater than 0.3 the undercut on the bottom surface of the first Ti seed layer 114-1 may be equal to or smaller than 0.3 and thus, the first Ti seed layer 114-1 may be included in the process window.

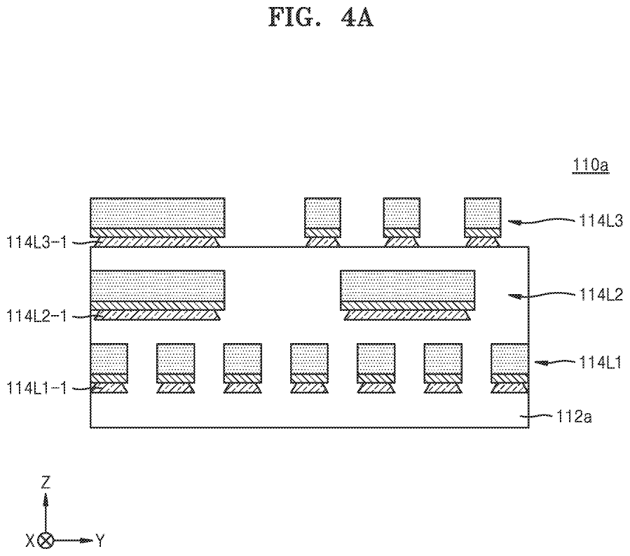

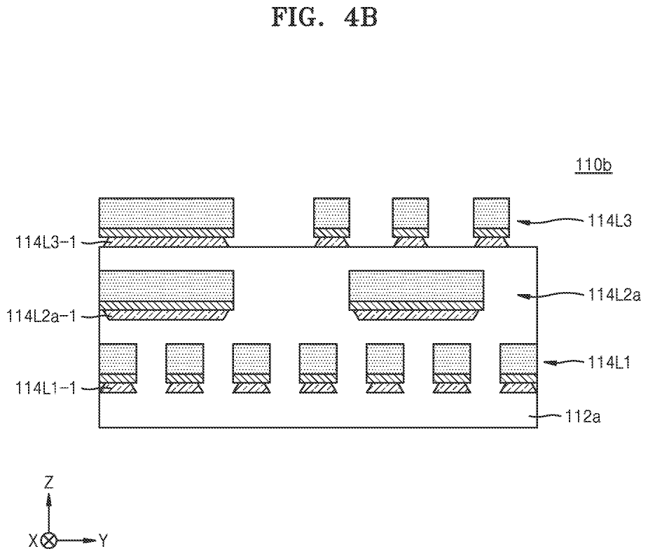

FIGS. 4A and 4B are cross-sectional views of various wiring layer structures of a first redistribution substrate 110a of the semiconductor package 100 shown in FIG. 1. Details described above with reference to FIGS. 1 to 3 will be briefly described or omitted.

Referring to FIG. 4A, the first redistribution substrate 110a of the semiconductor package 100 according to the present embodiment may include three first wiring layers 114L1, 114L2, and 114L3 in a body layer 112a. The three first wiring layers 114L1, 114L2, and 114L3 may respectively have different structures. In an implementation, in a lowermost layer, a plurality of the first wiring layers 114L1 may be arranged in a S/L structure. In an intermediate layer, a few first wiring layers 114L2 having a great width may be arranged, and may be arranged in a S/L structure or separate structures with different heights and intervals. In an uppermost layer, the first wiring layers 114L3 having a great width and the first wiring layers 114L3 having a small width may be mixed, and the plurality of first wiring layers 114L3 may be arranged in a S/L structure.

As shown in FIG. 4A, the first wiring layers 114L1, 114L2, and 114L3 may respectively include first Ti seed layers 114L1-1, 114L2-1, and 114L3-1 having a trapezoid structure in which a top portion is narrow and a bottom portion is wide. In other words, in the semiconductor package 100 according to the present embodiment, the first Ti seed layers 114L1-1, 114L2-1, and 114L3-1 of the first wiring layer 114L1, 114L2, and 114L3 in all layers may be formed using a fluoride etchant. Therefore, the first Ti seed layers 114L1-1, 114L2-1, and 114L3-1 having the trapezoid structure may be formed regardless of the widths of the first wiring layer 114L1, 114L2, and 114L3. The first wiring layers 114L1, 114L2, and 114L3 in different layers may be connected to one another through the first via contact 116.

Referring to FIG. 4B, a first redistribution substrate 110b of the semiconductor package 100 according to the present embodiment may include three first wiring layers 114L1, 114L2a, and 114L3 in the body layer 112a. The three first wiring layers 114L1, 114L2a, and 114L3 may respectively have different structures. In an implementation, in a lowermost layer, a plurality of first wiring layers 114L1 may be arranged in a S/L structure. In an intermediate layer, a few first wiring layers 114L2a having a great width may be arranged, and may be arranged in a S/L structure or separate structures with different heights and intervals. In an uppermost layer, the first wiring layers 114L3 having a great width and the first wiring layers 114L3 having a small width may be mixed, and the plurality of first wiring layers 114L3 may be arranged in a S/L structure.

As shown in FIG. 4B, the first wiring layers 114L1 and 114L3 on the lowermost layer and the uppermost layer may include the first Ti seed layers 114L1-1 and 114L3-1 each having a trapezoid structure having a smaller upper portion and a greater lower portion. In other words, in the semiconductor package 100 according to the present embodiment, the first Ti seed layers 114L1-1 and 114L3-1 in the first wiring layers 114L1 and 114L3 in the lowermost layer and the uppermost layer may be formed using a fluoride etchant. In addition, the first wiring layer 114L2a in the intermediate layer may include a second Ti seed layer 114L2a-1 having a reverse-trapezoid structure having a smaller lower portion and a greater upper portion. The second Ti seed layer 114L2a-1 of the first wiring layer 114L2a of the intermediate layer may be formed using H₂O₂ etchant.

As shown in FIG. 4B, the first wiring layer 114L2a in the intermediate layer may have a relatively great width in the second direction (the Y direction). Accordingly, even when the second Ti seed layer 114L2a-1 having the reverse-trapezoid structure is formed using H₂O₂ etchant, an adhesion with a lower layer may not be weakened. To conclude, in the case of the semiconductor package 100 according to the present embodiment, Ti seed layers may be formed using different etchant according to widths of the first wiring layers, and accordingly, the first redistribution substrate may include Ti seed layers having different structures according to layers.

FIGS. 5A to 5F are cross-sectional views of a process of manufacturing the first redistribution substrate 110 shown in FIG. 2A. FIGS. 5A to 5F will be described with reference to FIG. 2A, and details described above with reference to FIGS. 1 to 3 will be briefly described or omitted.

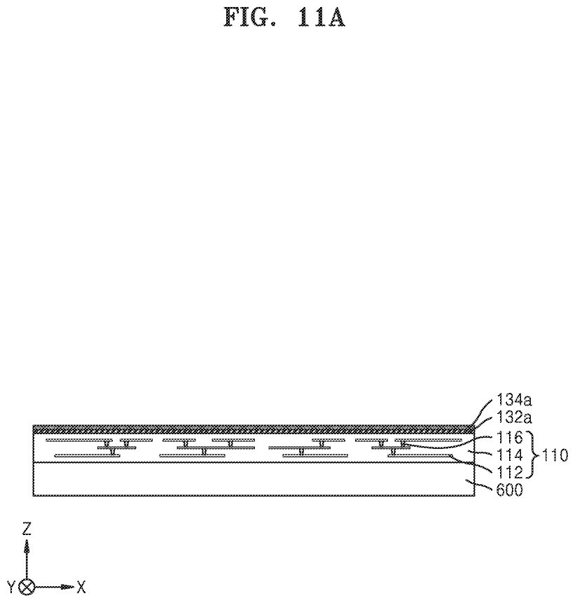

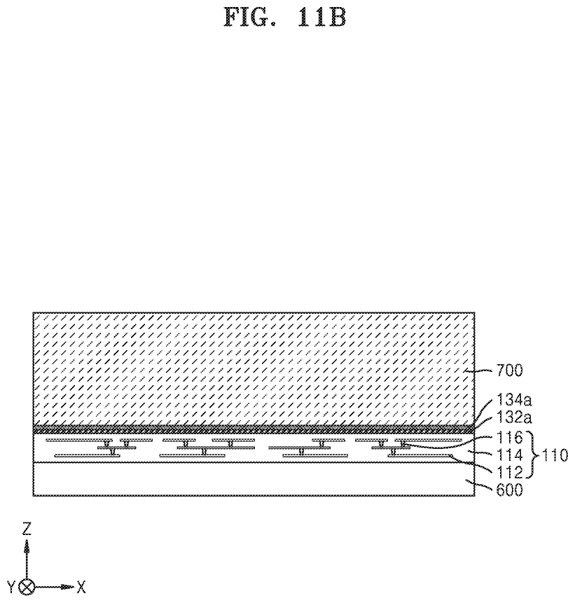

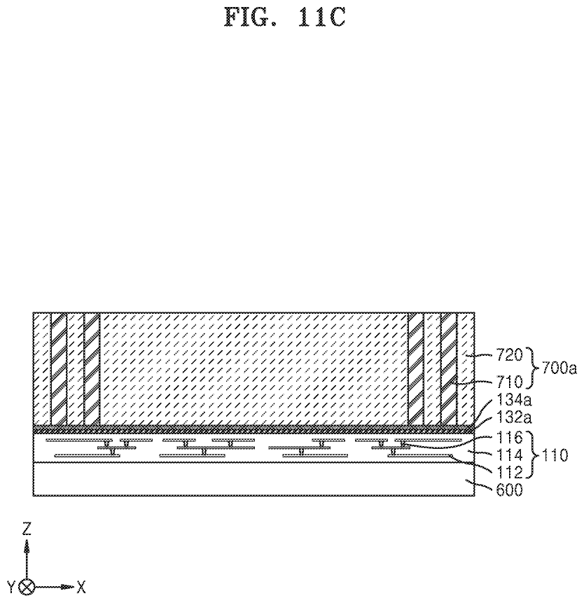

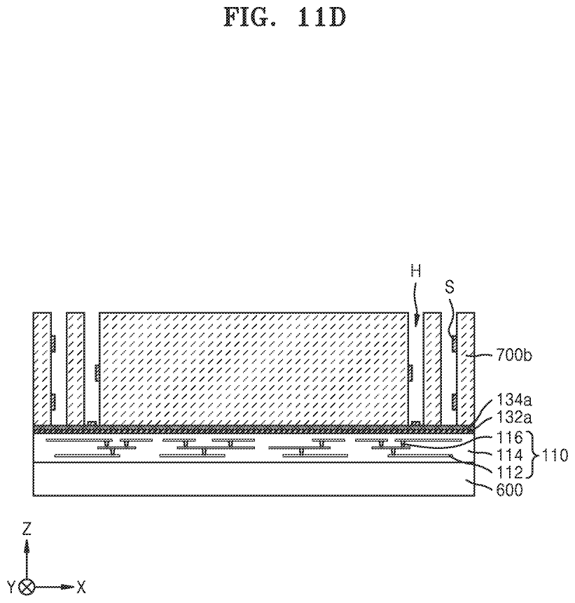

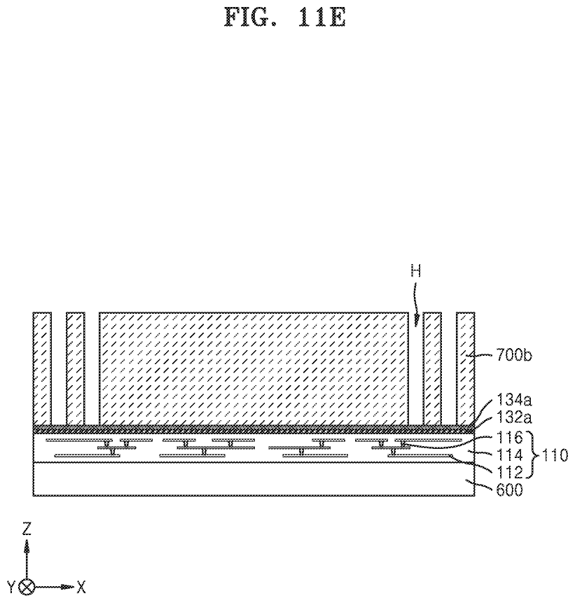

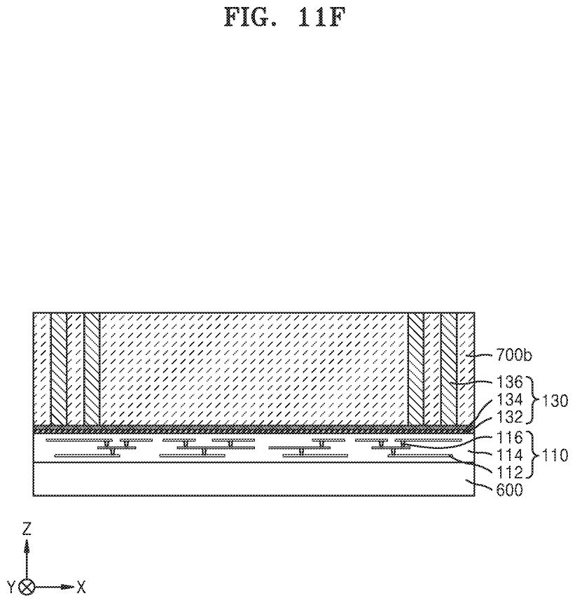

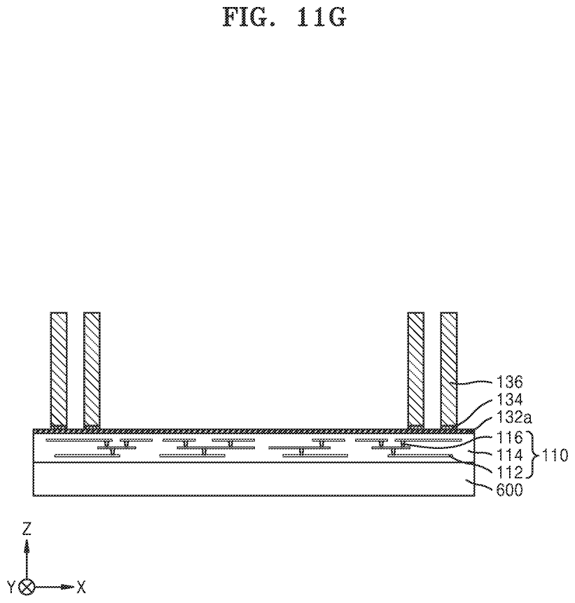

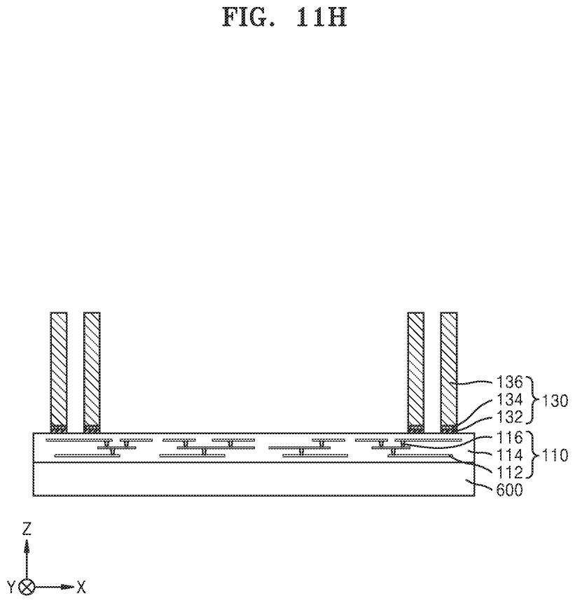

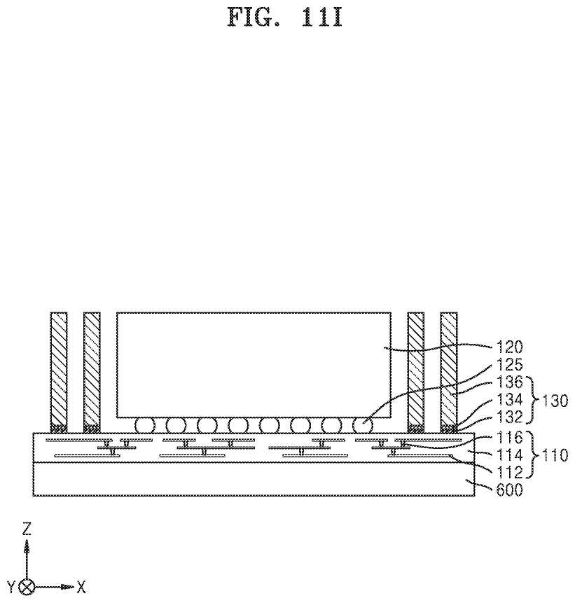

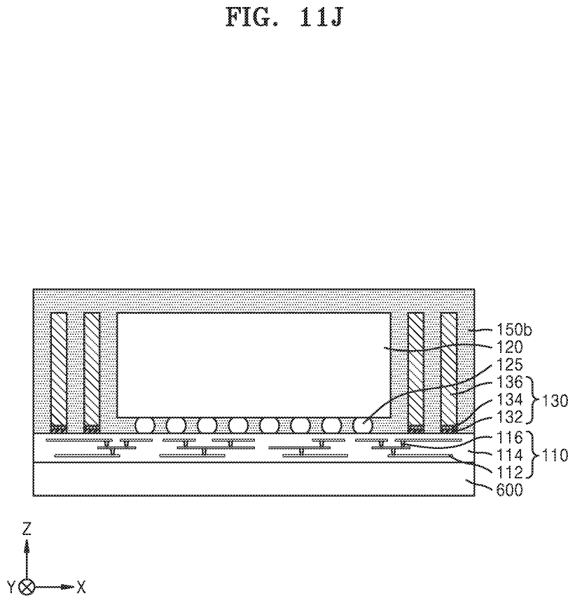

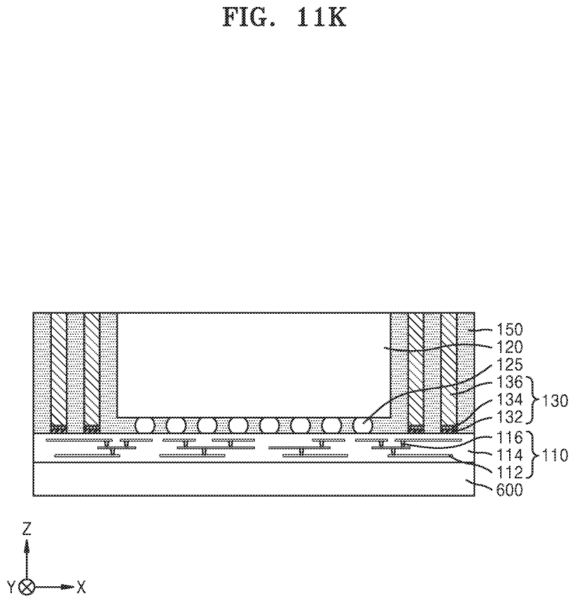

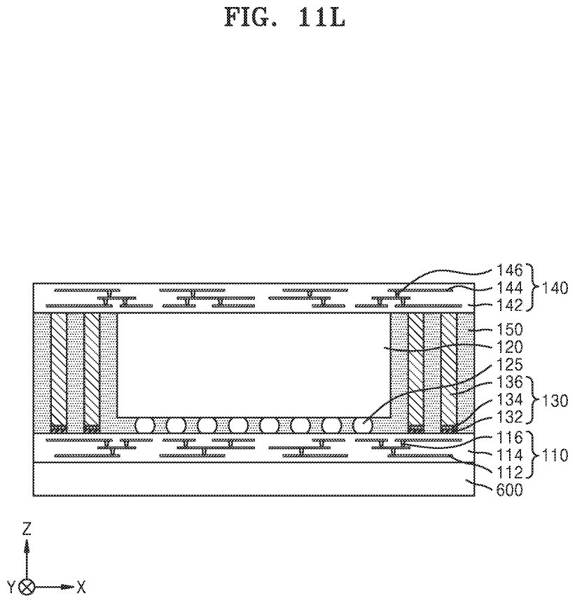

Referring to FIG. 5A, an initial Ti seed layer 114-1a and an initial Cu seed layer 114-2a may be on the first body layer 112. The first body layer 112 may include, e.g., a polymer layer. Each of the initial Ti seed layer 114-1a and the initial Cu seed layer 114-2a may be formed through a sputtering process. The initial Ti seed layer 114-1a and the initial Cu seed layer 114-2a may have various thicknesses according to sizes and materials of a wiring to form. In an implementation, in the semiconductor package 100 according to the present embodiment, when the Cu wiring 114-3 has a width smaller than or equal to 5 μm, the initial Ti seed layer 114-1a may have a thickness of from about 50 nm to about 100 nm or from about 100 nm to about 150 nm, and the initial Cu seed layer 114-2a may have a thickness of from about 200 nm to about 300 nm. Referring to FIG. 5B, subsequently, photoresist (PR) patterns 500 may be on the initial Cu seed layer 114-2a. The PR patterns 500 may have a L/S structure extending in the first direction (the X direction) and apart from one another in the second direction (the Y direction). The PR pattern 500 may be formed by forming a PR layer on the initial Cu seed layer 114-2a through spin coating and performing an exposure process and a develop process on the PR layer. A process of forming the PR pattern 500 may be more clearly understood from description with reference to FIGS. 11B to 11E.

Referring to FIG. 5C, after forming the PR pattern 500, the Cu wirings 114-3 may be formed through electroplating using the initial Ti seed layer 114-1a and the initial Cu seed layer 114-2a as seed layers. The Cu wirings 114-3 may have a L/S structure extending in the first direction (the X direction) and apart from one another in the second direction (the Y direction), to correspond to a shape of the PR pattern 500.

Referring to FIG. 5D, next, only the Cu wiring 114-3 may be left by removing the PR pattern 500. The PR pattern 500 may be removed through a strip/ashing process. By removing the PR pattern 500, the initial Cu seed layer 114-2a may be exposed between the Cu wirings 114-3.

Referring to FIG. 5E, next, a portion of the initial Cu seed layer 114-2a exposed between the Cu wirings 114-3 may be removed. The portion of the initial Cu seed layer 114-2a may be removed through an etching process using a Cu etchant. The Cu etchant may include, e.g., H₂O₂ and acid. Here, the acid may include sulfuric acid, organic acid, or phosphoric acid. The portion of the initial Cu seed layer 114-2a may be maintained only under the Cu wiring 114-3 by removing the exposed portion of the initial Cu seed layer 114-2a, and therefore, the first Cu seed layer 114-2 may be formed.

Referring to FIG. 5F, after forming the first Cu seed layer 114-2, a portion of the initial Ti seed layer 114-1a exposed between the Cu wirings 114-3 may be removed. The portion of the initial Ti seed layer 114-1a may be removed through an etching process using a fluoride etchant. Here, the fluoride etchant may include an organic acid or an inorganic acid, an F-containing source, a first additive of a halide, and a second additive of an azole-based compound. The organic acid may include, e.g., citric acid (C₆H₈O₇). The inorganic acid may include, e.g., nitric acid (HNO₃). The F-containing source may include, e.g., NH₄F, NH₄BF₄, N(Bu)₄F, N(Bu)₄BF₄, NH₄HF₂, NH₄PF₆, N(Bu)₄PF₆, HF, CF₄COOH, and anhydrous hydrofluoric acid. As a negative-ion compound, the first additive may include e.g., CaF, NaCl, AgBr, or Kl. As a corrosion inhibitor, the second additive may include thiazole, benzotriazole, imodazole, thiadiazole, or amine.

In terms of content, the fluoride etchant may include deionized water in 80% to 90%, the organic acid or inorganic acid in 5% or 10%, the F-containing source in 3% to 5%, the first additive in 2% or less, and the second additive in 2% or less. In addition, the fluoride etchant may have a pH of from about 2 to about 4.

For reference, when etching the initial Ti seed layer 114-1a using the fluoride etchant, undercuts may be reduced through competition reaction between fluoride negative ions (F⁻) and new negative ions from the first additive. Furthermore, the first Ti seed layer 114-1 having the trapezoid structure having a side slope from about 65° to about 90° may be formed. The second additive may inhibit etching of Cu. Accordingly, in the process of etching the initial Ti seed layer 114-1a, widths of the Cu wiring 114-3 and the first Cu seed layer 114-2 may be maintained without decrease.

By removing the exposed portion of the initial Ti seed layer 114-1a, a portion of the initial Ti seed layer 114-1a may be maintained only in the bottom portion of the first Cu seed layer 114-2, and therefore, the first Ti seed layer 114-1 may be formed. The first wiring layer 114 may be completely formed by forming the first Ti seed layer 114-1.

Next, a polymer layer covering the first wiring layer 114 may be on the first body layer 112. In addition, a pad connected to the first wiring layer 114 may be on the bottom surface and top surface of the first body layer 112. Through the aforementioned process, the first redistribution substrate 110 may be completely formed. However, when multiple layers of the first wiring layers 114 are in the first body layer 112, the processes shown in FIGS. 5A to 5F may be repeated for each first wiring layer 114.

In addition, the first redistribution substrate 110 may be manufactured in the form of a large-size initial redistribution substrate. Next, the first redistribution substrate 110 may be singulated into a plurality of first redistribution substrates 110 through singulation. In addition, prior to the singulation, a series of processes such as mounting corresponding semiconductor chips on the plurality of first redistribution substrate 110 of the initial distribution substrate may be performed, and then, the first redistribution substrate 110 may be singulated in the form of singulated semiconductor packages 100 through the singulation. A structure of a semiconductor package formed through the aforementioned process is referred to as a wafer level package (WLP) structure.

FIGS. 6A to 6C are enlarged cross-sectional views of a portion A of the semiconductor package 100 shown in FIG. 1. FIGS. 6A to 6C will be described with reference to FIG. 1, and details described above with reference to FIGS. 1 to 3 will be briefly described or omitted.

Referring to FIG. 6A, in the semiconductor package 100 according to the present embodiment, the through post 130 may include the third Ti seed layer 132, the second Cu seed layer 134, and the Cu post 136. The third Ti seed layer 132 may be formed using a fluoride etchant. Accordingly, as shown in FIG. 6A, the third Ti seed layer 132 may have a trapezoid structure in which an upper portion is narrow and a lower portion is wide.

Referring to FIG. 6B, in the semiconductor package 100 according to the present embodiment, a through post 130a may include a fourth Ti seed layer 132a, the second Cu seed layer 134, and the Cu post 136. The fourth Ti seed layer 132a may be formed using H₂O₂ etchant. Accordingly, as shown in FIG. 6B, the fourth Ti seed layer 132a may have a reverse-trapezoid structure in which a lower portion is narrow and an upper portion is wide.

Referring to FIG. 6C, in the semiconductor package 100 according to the present embodiment, a through post 130b may include the second Cu seed layer 134 and the Cu post 136. That is, the through post 130b may not include a Ti see layer. As the through post 130b does not include the Ti seed layer, the second Cu seed layer 134 may be directly on the first body layer 112.

FIGS. 7 to 10 are cross-sectional views of a structure of a semiconductor device according to example embodiments. Details described above with reference to FIGS. 1 to 6C will be briefly described or omitted.

Referring to FIG. 7, the semiconductor package 100a according to the present embodiment may be different from the semiconductor package 100 shown in FIG. 1 in terms of a structure of a sealing material 150a and a relationship between positions of the semiconductor chip 120 and the second redistribution substrate 140 according to the structure of the sealing material 150a. More particularly, in the semiconductor package 100a according to the present embodiment, the sealing material 150a may cover the top surface of the semiconductor chip 120. Accordingly, there may be a gap G corresponding to a thickness of the sealing material 150a between the semiconductor chip 120 and the second redistribution substrate 140. The aforementioned structure of the sealing material 150a may be implemented by removing some of the sealing material 150a on the top surface of the semiconductor chip 120 in a backgrinding process of the sealing material 150a. The structure of the sealing material 150a will be further described with reference to a method of manufacturing a semiconductor package shown in FIGS. 11A to 11L.

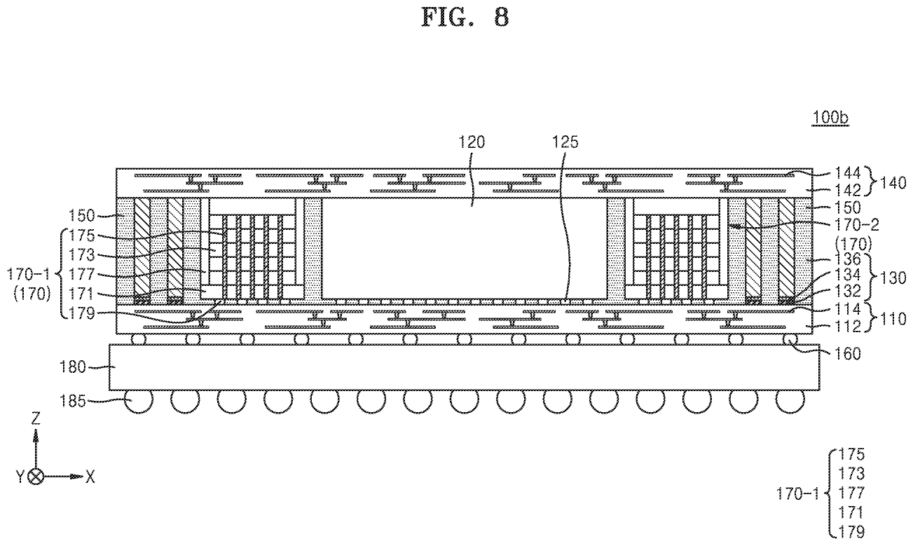

Referring to FIG. 8, a semiconductor package 100b according to the present embodiment may be different from the semiconductor package 100 shown in FIG. 1 for further including a stacked memory package 170 and a package substrate 180. More particularly, the semiconductor package 100b according to the present embodiment may include the first redistribution substrate 110, the semiconductor chip 120, the through post 130, the second redistribution substrate 140, the sealing material 150, the external contact terminal 160, the stacked memory package 170, and the package substrate 180.

Except that the stacked memory package 170 may be above the first redistribution substrate 110, the first redistribution substrate 110, the semiconductor chip 120, the through post 130, the second redistribution substrate 140, the sealing material 150, and the external contact terminal 160 may be as described with reference to the semiconductor package 100 shown in FIG. 1.

The stacked memory package 170 may include a first stacked semiconductor memory package 170-1 and a second stacked memory package 170-2. In an implementation, the stacked memory package 170 may be above the first redistribution substrate 110 at two sides of the semiconductor chip 120. In an implementation, one or at least three stacked memory packages 170 may be above the first redistribution substrate 110.

The stacked memory package 170 may include, e.g., a high bandwidth memory (HBM) chip. To further describe the stacked memory package 170, the stacked memory package 170 may include a base chip 171 and a plurality of core chips 173 on the base chip 171. In addition, the base chip 171 and the core chips 173 may include a through electrode 175 therein. A core chip at top of the core chips 173 may not include the through electrode 175.

The base chip 171 may include logic devices. Accordingly, the base chip 171 may include a logic chip. The base chip 171 may be under the core chips 173, integrate signals from the core chips 173 and transmit the signals to outside, and may transmit signals and power from outside to the core chips 173. Accordingly, the base chip 171 may be referred to as a buffer chip or a control chip. Each of the core chips 173 may include a memory chip including a plurality of memory devices. In an implementation, each of the core chips 173 may include a DRAM chip including a plurality of DRAM devices. The core chips 173 may be stacked on the base chip 171 through pad-to pad bonding, bonding using a bonding member, or bonding using an anisotropic conductive film (ACF).

Bumps 179 may be on a bottom surface of the base chip 171. The bump 179 may be connected to the through electrode 175. The bumps 179 may be a solder. However, according to an embodiment, the bumps 179 may also have a structure including a pillar and a solder. The stacked memory package 170 may be mounted above the first redistribution substrate 110 through the bumps 179. The core chips 173 on the base chip 171 may be sealed by an interior sealing material 177. However, the core chip at the top of the core chips 173 may be not covered by the interior sealing material 177. However, in other embodiments, a top surface of the core chip at the top of the core chips 173 may be covered by the interior sealing material 177.

The package substrate 180, which may be a support substrate on which the first redistribution substrate 110 may be mounted, may include at least one wiring layer therein. When the wiring layer includes multiple layers, wiring layers on different layers may be connected to one another through via contacts. In some embodiments, the package substrate 180 may also include a through electrode directly connecting substrate pads on top surface and a bottom surface of the package substrate 180. A protective layer such as a solder resist may be on the top surface and bottom surface of the package substrate 180. The substrate pads of the package substrate 180 may be connected to the wiring layers and exposed from the protective layer.

The package substrate 180 may be, e.g., a ceramic substrate, a printing circuit board (PCB), an organic substrate, or an interposer substrate. According to embodiments, the package substrate 180 may include an active wafer such as a silicon wafer. External contact terminals 185 such as bumps or solder balls may be on a bottom surface of the package substrate 180. The external contact terminals 185 may mount the semiconductor package 100b on an external system substrate or main board. In some embodiments, the package substrate 180 may be omitted, and the semiconductor package 100b may be mounted on an external system substrate or main board through the external contact terminal 160 of the first redistribution substrate 110.

The sealing material 150 may cover and seal side surfaces of the semiconductor chip 120, the through post 130, and the stacked memory package 170 on the first redistribution substrate 110. As shown in FIG. 8, the sealing material 150 may not cover top surfaces of the semiconductor chip 120 and the stacked memory package 170. However, in other embodiments, the sealing material 150 may cover the top surface of the stacked memory package 170. The semiconductor package 100b according to the present embodiment may further include, on the package substrate 180, an external sealing material covering and sealing the first redistribution substrate 110, the second redistribution substrate 140, and the sealing material 150. In addition, similar to a semiconductor package 1000 shown in FIG. 10, in some embodiments, an upper package may be on the second redistribution substrate 140.

For reference, the semiconductor package 100b according to the present embodiment may correspond to a 2.5D package structure. In general, a 2.5D package structure may be implemented through an Si interposer, and the semiconductor package 100b according to the present embodiment may correspond to a structure in which the Si interposer may be replaced with the first redistribution substrate 110. Accordingly, the semiconductor package 100b according to the present embodiment may also correspond to a 2.5D package structure. A 2.5D package structure may be a concept relative to a three-dimensional package structure in which all semiconductor chips may be stacked together on a package substrate and there is no Si interposer or the first redistribution substrate 110. Both the 2.5D package structure and the 3D package structure may be included in a system in package (SIP) structure.

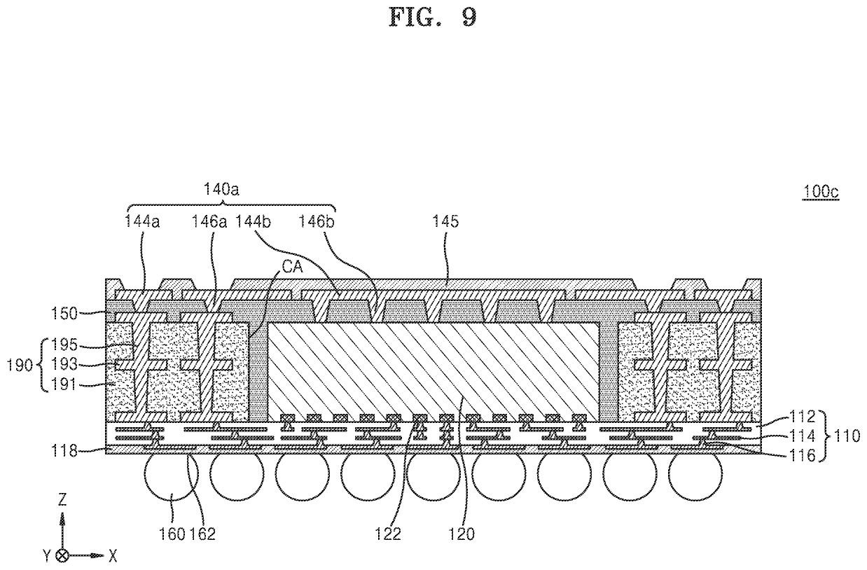

Referring to FIG. 9, a semiconductor package 100c according to the present embodiment may be different from the semiconductor package 100 shown in FIG. 1 in that the semiconductor package 100c may include a core layer 190 instead of the through post 130. Furthermore, a structure of a second redistribution substrate 140a may be slightly different from that of the semiconductor package 100 shown in FIG. 1.

More particularly, the semiconductor package 100c according to the present embodiment may include the first redistribution substrate 110, the semiconductor chip 120, the second redistribution substrate 140a, the sealing material 150, the external contact terminal 160, and the core layer 190. Except that second via contacts 146a and 146b of the second redistribution substrate 140a contact a core wiring layer 193 of the core layer 190 and the top surface of the semiconductor chip 120 through the sealing material 150, the first redistribution substrate 110, the semiconductor chip 120, the sealing material 150, and the external contact terminal 160 may be as described with reference to the semiconductor package 100 shown in FIG. 1.

The core layer 190 may include a through hole CA through a top surface and a bottom surface of the core layer 190. According to embodiments, the through hole CA may not completely pass through the bottom surface of the core layer 190 and may have the form of a cavity. As shown in FIG. 9, the through hole CA may be in a center of the core layer 190. One core hole CA may be in the core layer 190, and one semiconductor chip 120 may be in the through hole CA. In an implementation, two or more through holes and two or more semiconductor chips corresponding thereto may be in the core layer 190, and two or more semiconductor chips may be in one through hole.

The core layer 190 may include a core insulating layer 191, the core wiring layer 193, and a core via 195. The core wiring layers 193 may be in a multiple-layer structure and may be electrically to one another through the core via 195. FIG. 9 illustrates that the core wiring layer 193 may be in a three-layer structure. The core insulating layer 191 may have a multiple-layer structure to correspond to the multiple-layer structure of the core wiring layer 193. For convenience, FIG. 9 illustrates the core insulating layer 191 as a single layer.

The core insulating layer 191 may include an insulating material, e.g., a thermoset resin such as epoxy resin or a thermoplastic resin such as polyimide, and may further include an inorganic filler. In addition, in addition to the inorganic filler, the core insulating layer 191 may also include a resin impregnanted into a core material such as glass fiber, glass cloth, glass fabric, e.g., prepreg, Ajinomoto build-up film (ABF), FR-4, or bismaleimide triazine (BT).

The sealing material 150 may cover and seal the semiconductor chip 120 in the through hole CA. The sealing material 150 may fill a space in the through hole CA of the core layer 190 and extend to a top surface of the core layer 190. In other words, the sealing material 150 may cover a space between the semiconductor chip 120 and an inner wall of the through hole CA and the top surfaces of the semiconductor chip 120 and the core layer 190. According to embodiments, the sealing material 150 may fill a space between the semiconductor chip 120 and the first redistribution substrate 110.

The second redistribution substrate 140a may be on the semiconductor chip 120, the sealing material 150, and the core layer 190. The second redistribution substrate 140a may include two wiring layers 144a and 144b and the second via contacts 146a and 146b. The second wiring layer 144a and the second via contact 146a at a peripheral portion may be above the core layer 190 and electrically connected to the core wiring layer 193 of the core layer 190. In addition, the second wiring layer 144b and the second via contact 146b at a center portion may be on the semiconductor chip 120, and the second via contact 146b may contact the semiconductor chip 120 through the sealing material 150. In some embodiments, the second via contact 146b in the center portion may be omitted.

A first passivation layer 145 may be on a top surface of the second redistribution substrate 140a, and a second passivation layer 118 may be on the bottom surface of the first redistribution substrate 110. The first passivation layer 145 and the second passivation layer 118 may cover and protect the second redistribution substrate 140a and the first redistribution substrate 110. The first passivation layer 145 and the second passivation layer 118 may include an insulating material, e.g., a resin. A portion of the second wiring layer 144a exposed through an opening of the first passivation layer 145 may function as a substrate pad. As a bump 215 (see FIG. 10) of an upper package may be on the substrate pad and at least one upper package 200 (see FIG. 10) may be on the semiconductor package 100c through the bump, a package on package (POP) structure may be implemented.

The semiconductor chip 120, which has a structure being directly connected to the first wiring layer 114 of the first redistribution substrate 110 through the first via contact 116, may be mounted on the first redistribution substrate 110. However, similar to the semiconductor package 100 shown in FIG. 1, also in the semiconductor package 100c according to the present embodiment may be mounted above the first redistribution substrate 110 through the bump. In addition, the semiconductor package 100c may be formed in a singulated manner through the singulation of a large-sized panel including a plurality of the core layers 190, and accordingly, may correspond to a panel level package (PLP).

Referring to FIG. 10, the semiconductor package 1000 according to the present embodiment may be different from the semiconductor package 100 shown in FIG. 1 for further including the upper package 200. More particularly, the semiconductor package 1000 according to the present embodiment may include a lower package 100 and the upper package 200. Therefore, the semiconductor package 1000 according to the present embodiment may have a POP structure. The lower package 100 may be substantially identical to the semiconductor package 100 shown in FIG. 1. The semiconductor package 1000 may include the semiconductor package 100a, the semiconductor package 100b, or the semiconductor package 100c in FIGS. 7 to 9 as the lower package.

The upper package 200 may include at least one second semiconductor chip 210, at least one passive element 220, and an upper sealing material 230. The second semiconductor chip 210 may include a memory semiconductor chip. In an implementation, the memory semiconductor chip may include a volatile memory device, e.g., DRAM or SRAM, or a non-volatile memory device such as flash memory. In an implementation, in some embodiments, the second semiconductor chip 210 may also include a logic semiconductor chip.

As shown in FIG. 10, the upper package 200 may include two second semiconductor chips 210-1 and 210-2. The two second semiconductor chips 210-1 and 210-2 may include a same type of semiconductor chips, or may include different types of semiconductor chips. In an implementation, the upper package 200 may include one or at least three second semiconductor chips 210. The second semiconductor chips 210 may be in a stack structure above the second redistribution substrate 140. In other words, the second semiconductor chips 210 may be in the stack structure above the second redistribution substrate 140, without being adjacent to each other above the second redistribution substrate 140 as shown in FIG. 10.

The second semiconductor chip 210 may be above the second redistribution substrate 140 through a bump 215. In some embodiments, the second semiconductor chip 210 may be above the second redistribution substrate 140 through a wire instead of the bump 215. In addition, when the second semiconductor chips 210 are in the stack structure above the second redistribution substrate 140 through the wire, the second semiconductor chips 210 may be stacked in a step structure or a zigzag structure.

The passive element 220 may include two-terminal elements such as a resistor, a capacitor, and an inductor. In FIG. 10, two passive elements 220 may be on the second redistribution substrate 140.

The upper sealing material 230 may seal the second semiconductor chip 210 and the passive element 220 to protect the second semiconductor chip 210 and the passive element 220 from physical and/or chemical damages from outside. In addition, the upper sealing material 230 may fill a space between the bumps 215 between the second semiconductor chip 210 and the second redistribution substrate 140.

FIGS. 11A to 11L are cross-sectional views of a process of manufacturing the semiconductor package 100 shown in FIG. 1. FIGS. 11A to 11L will be described with reference to FIG. 1, and details described above with reference to FIGS. 1 to 10 will be briefly described or omitted.

Referring to FIG. 11A, in the method of manufacturing the semiconductor package, first, the first redistribution substrate 110 may be on a carrier substrate 600. A method of forming the first redistribution substrate 110 may be as described above with reference to FIGS. 5A to 5F. The carrier substrate 600 may include a large-sized substrate, e.g., a wafer. In addition, an initial redistribution substrate on the carrier substrate 600 may have a large size including a plurality of the first redistribution substrate 110. A semiconductor package structure singulated through a singulation process after subsequence components may be formed on the initial redistribution substrate, as described above, is referred to as a WLP structure. However, for convenience of explanation, FIGS. 11A to 11L only illustrate one first redistribution substrate 110 and components corresponding thereto.

Next, an initial Ti seed layer 132a and an initial Cu seed layer 134a may be formed on the first redistribution substrate 110. The initial Ti seed layer 132a and the initial Cu seed layer 134a may be used in a following electric plating process for forming the Cu post 136. In some embodiments, the initial Ti seed layer 132a may be omitted. In this case, the through post 130b shown in FIG. 6C may be formed.

Referring to FIG. 11B, subsequently, a PR layer 700 may be formed on the initial Cu seed layer 134a of the first redistribution substrate 110. The PR layer 700 may be formed through, e.g., spin coating.

Referring to FIG. 11C, after the PR layer 700 is formed, an exposure process may be performed. The exposure process may be performed using a mask including a certain pattern. In an implementation, light may be transmitted through a transparent portion of a transmissive mask to irradiate light on a portion of the PR layer 700. Chemical properties of the portion of the PR layer 700 to which the light has been irradiated may be modified. In an implementation, after the exposure process, the PR layer 700a may be divided into an unexposed portion 710 and an exposed portion 720. As shown in FIG. 11C, the exposed portion 720 may be at a peripheral portion of the first redistribution substrate 110.

Referring to FIG. 11D, after the exposure process, a develop process may be performed on the PR layer 700a. In the develop process, e.g., the exposed portion 720 may be removed. In an implementation, the PR layer 700a may include a positive PR. As the exposed portion 720 is removed through the develop process, a PR pattern 700b may be formed. The PR pattern 700b may include a plurality of through holes H. The initial Cu seed layer 134a may be exposed through a bottom surface of the through holes H. After the develop process, byproducts S such as PR scum may remain in the through holes H. According to embodiments, a negative PR may be used, and when the negative PR is used, the unexposed portion may be removed in the develop process.

Referring to FIG. 11E, the byproducts S may be removed through a cleaning process. A process of removing the PR scums may be referred to as a PR descum process. The PR descum process may be included in the cleaning process.

Referring to FIG. 11F, after the cleaning process, the Cu post 136 may be formed in the through holes H through electric plating. The Cu post 136 may be Cu. By forming the Cu post 136, all portions included in the through post 130 may be formed. However, in a following process to planarize the sealing material 150, a portion of the Cu post 136 may be removed.

Referring to FIG. 11G, after the Cu post 136 is formed, the PR pattern 700b may be removed. The PR pattern 700b may be removed through a strip/ashing process. After removing the PR pattern 700b, the initial Cu seed layer 134a may be exposed between the through posts 130. Next, the second Cu seed layer 134 may be formed by removing an exposed portion of the initial Cu seed layer 134a. The exposed portion of the initial Cu seed layer 134a may be removed through an etching process using a Cu etchant. The Cu etchant may be as described above with reference to FIG. 5E. A top surface of the initial Ti seed layer 132a may be exposed due to removal of the initial Cu seed layer 134a. In addition, a remaining portion of the initial Cu seed layer 134a on a bottom surface of the Cu post 136 may be the second Cu seed layer 134.

Referring to FIG. 11H, next, the exposed portion of the initial Ti seed layer 132a may be removed to form the third Ti seed layer 132. The portion of the initial Ti seed layer 132a may be removed through an etching process using a fluoride etchant. The fluoride etchant may be as described above with reference to FIG. 5F. The top surface of the first body layer 112 may be exposed due to removal of the initial Ti seed layer 132a. In addition, a portion of the initial Ti seed layer 132a on a bottom surface of the second Cu seed layer 134 may be formed into the third Ti seed layer 132 having a trapezoid structure due to the fluoride etchant.

In addition, in a semiconductor package, a through post may have a relative great width. Accordingly, the initial Ti seed layer 132a may be removed by using H₂O₂ etchant. In that case, as in the through post 130a shown in FIG. 6B, the fourth Ti seed layer 132a having a reverse-trapezoid structure may be on the bottom surface of the second Cu seed layer 134.

Referring to FIG. 11I, the semiconductor chip 120 may be mounted above the center portion of the first redistribution substrate 110. The semiconductor chip 120 may be mounted in a flip-chip structure above the first redistribution substrate 110 using the bumps 125. According to embodiments, a underfill may fill a space between the bumps 125 between the first redistribution substrate 110 and the semiconductor chip 120.

Referring to FIG. 11J, after mounting the semiconductor chip 120, a sealing material 150b covering the semiconductor chip 120 and the through post 130 may be formed on the first redistribution substrate 110. The sealing material 150 may cover side surfaces and top surfaces of the semiconductor chip 120 and the through post 130. Materials of the sealing material 150b may be the same as description of the sealing material 150 of the semiconductor package 100 shown in FIG. 1.

Referring to FIG. 11K, next, a planarization process to remove an upper portion of the sealing material 150b may be performed. The planarization process may be performed, e.g., through CMP. The top surface of the semiconductor chip 120 and the top surface of the through post 130 may be exposed from the sealing material 150. In other words, after the planarization process, the top surface of the semiconductor chip 120, the top surface of the through post 130, and the top surface of the sealing material 150 may be substantially coplanar.

In some embodiments, not the top surface of the semiconductor chip 120 but only the top surface of the through post 130 may be exposed through the planarization process. In that case, as the sealing material 150a remains on the top surface of the semiconductor chip 120, a structure of the semiconductor package 100a shown in FIG. 7 may be formed.

Referring to FIG. 11L, subsequently, the second redistribution substrate 140 may be formed on the semiconductor chip 120, the through post 130, and the sealing material 150. Description of the second redistribution substrate 140 may be the same as the description of the second redistribution substrate 140 of the semiconductor package 100 shown in FIG. 1. Next, the semiconductor package 100 shown in FIG. 1 may be formed by separating the carrier substrate 600 and placing the external contact terminal 160 on the bottom surface of the first redistribution substrate 110. As described above, as a wafer level package may be formed through the process shown in FIGS. 11A to 11L, the semiconductor package 100 shown in FIG. 1 may be substantially formed through a singulation process to separate the semiconductor package into singulated semiconductor packages.

By way of summation and review, according to rapid development in electronic business and requirements from users, sizes and weights of electronic devices are being more and more reduced. Reduction in sizes and weights of electronic devices incurs reduction in sizes and weights of semiconductor packages used for electronic devices. In addition, high reliability as well as high performance and large capacities are required for semiconductor packages. According to improvement in performance and capacities of semiconductor packages, power consumption of semiconductor packages is increasing. Accordingly, the structure of semiconductor packages is being considered more important to cope with sizes and performances of semiconductor packages and to stably supply power to semiconductor packages.

A semiconductor package including a wiring layer having a fine pattern structure with improved reliability, and a method of manufacturing the semiconductor package is disclosed. Technical goals to achieve and other goals may be clearly understood to those skilled in the art according to the description.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor package comprising:
a first redistribution substrate including a first body layer and a first wiring layer in the first body layer;
a semiconductor chip on the first redistribution substrate;
a through post around the semiconductor chip and on the first redistribution substrate; and
a second redistribution substrate on the semiconductor chip and the through post, wherein:
the first wiring layer includes a first titanium seed layer, and
the first titanium seed layer has a vertical cross-section of a trapezoid structure in which a top surface is narrow and a bottom surface is wide.

2. The semiconductor package as claimed in claim 1, wherein:
the first wiring layer includes a copper seed layer and a copper wiring on the first titanium seed layer, and
a polymer layer is under the first titanium seed layer.

3. The semiconductor package as claimed in claim 2, wherein an area of the top surface of the first titanium seed layer is smaller than a bottom surface of the copper seed layer and is equal to or greater than 65% of an area of the bottom surface of the copper seed layer.

4. The semiconductor package as claimed in claim 1, wherein:
a plurality of the first wiring layer extend in a first direction on a certain layer in the first body layer and are apart from one another in a second direction perpendicular to the first direction, and
the first wiring layer having a first width and being at an interval less than or equal to 5 μm in the second direction.

5. The semiconductor package as claimed in claim 1, wherein a side slope of the trapezoid structure is from about 65° to about 90°.

6. The semiconductor package as claimed in claim 1, wherein:
the first redistribution substrate further includes, in the first body layer, a second wiring layer on a layer different from a layer on which the first wiring layer is arranged, and
the second wiring layer includes the first titanium seed layer.

7. The semiconductor package as claimed in claim 1, wherein:
the first redistribution substrate further includes, in the first body layer, a second wiring layer on a layer different from a layer on which the first wiring layer is arranged, and
the second wiring layer includes a second titanium seed layer having a vertical cross-section of a reverse-trapezoid structure and in which a top surface is wide and a bottom surface is narrow.

8. The semiconductor package as claimed in claim 1, wherein:
the first wiring layer is in a multiple-layer structure in the first body layer, and
the first wiring layer being adjacent to a second wiring layer and connected to one another through via contacts.

9. The semiconductor package as claimed in claim 1, wherein:
the second redistribution substrate includes a second body layer and a second wiring layer in the second body layer, and
the second wiring layer includes a third titanium seed layer having a vertical cross-section of a trapezoid structure in which a top surface is narrow and a bottom surface is wide.

10. The semiconductor package as claimed in claim 1, wherein the through post includes a fourth titanium seed layer having a vertical cross-section of a trapezoid structure in which a top surface is narrow and a bottom surface is wide.

11. The semiconductor package as claimed in claim 1, wherein:
the semiconductor chip includes an application processor chip, and
the semiconductor package further includes an upper package arranged on the second redistribution substrate through contact terminals and including a memory chip.

12. A semiconductor package comprising:
a first redistribution substrate;
semiconductor chips on the first redistribution substrate;
a through post around the semiconductor chips and on the first redistribution substrate;
a sealing material surrounding a side surface of the through post, and covering and sealing the semiconductor chips;
a second redistribution substrate on the sealing material and the through post; and
an external contact terminal in a fan-out structure on a bottom surface of the first redistribution substrate, wherein:
the first redistribution substrate and the second redistribution substrate each include a body layer and a wiring layer in the body layer,
the wiring layer includes a first titanium seed layer having a vertical cross-section of a trapezoid structure in which a top surface is narrow and a bottom surface is wide, a copper layer on the first titanium seed layer, and a copper wiring on the copper seed layer, and
a side slope of the trapezoid structure is from about 65° to about 90°.

13. The semiconductor package as claimed in claim 12, wherein:
a plurality of the wiring layer extend in a first direction on a certain layer in the body layer and are apart from one another in a second direction perpendicular to the first direction,
the wiring layer having a first width and being at an interval less than or equal to 5 μm in the second direction, and
a second width of the bottom surface of the first titanium seed layer in the second direction is smaller than the first width of the wiring layer.

14. The semiconductor package as claimed in claim 12, wherein:
at least one of the first redistribution substrate and the second redistribution substrate further includes, in the body layer, an additional wiring layer on a layer different from a layer on which the wiring layer is arranged, and
the additional wiring layer includes the first titanium seed layer or a second titanium seed layer having a vertical cross-section of a reverse-trapezoid structure in which a top surface is wide and a bottom surface is narrow.

15. The semiconductor package as claimed in claim 12, wherein:
the semiconductor chip includes an application processor chip, and
the semiconductor package further includes an upper package formed on the second redistribution substrate through contact terminals and including a memory chip.

16-25. (canceled)
